(19) United States
(12) Patent Application Publication
(10) Pub. No.: US 2010/0054352 A1
(43) Pub. Date: Mar. 4, 2010

(54) Correlation-based detection in a cognitive radio system

(75) Inventors: Anu Huttunen, Helsinki (FI); Jari Junell, Espoo (FI); Marko Kosunen, Helsinki (FI)

Correspondence Address: HARRINGTON & SMITH, PC, 4 RESEARCH DRIVE, Suite 202, SHELTON, CT, 06484-6212, US

(73) Assignee: Nokia Corporation

(21) Appl. No.: 12/231,226

(22) Filed: Aug. 28, 2008

(51) Int. Cl. H03D 1/00; H04L 27/28

(52) U.S. Cl. 375/260; 375/340

(57) ABSTRACT

Samples are extracted from a received signal. For each of a plurality of candidate cyclic frequencies, cyclic covariance of the received signal is determined using a Fourier transform FT having a length that is less than the number of extracted samples. The frequency channel within which the signal was received is chosen for opportunistic/cognitive radio transmissions when none of the plurality of candidate cyclic frequencies exhibits a peak that exceeds a threshold, or results are transmitted for collaborative sensing. The extracted samples may be filtered and decimated prior to executing the FT, and the length of the FT depends on the number of samples that remain. Decimating is at a rate that depends on a bandwidth of the filtering. The bandwidth of filtering is determined by the lowest cyclic frequency where the signal to be detected exhibits cyclostationarity. Each of the candidate cyclic frequencies are near zero and determining the covariance employs a windowing function centered on zero cyclic frequency.

### TECHNICAL FIELD

The teachings herein relate generally to wireless networks and devices such as cognitive radios that operate to sense spectrum to determine unused spectrum which they may opportunistically use while avoiding interference with primary users.

### BACKGROUND

Underutilization of many parts of radio frequency spectrum has increased the interest in dynamic spectrum allocation. Cognitive radios have been suggested as an enabling technology for dynamic allocation of spectrum resources. Spectrum sensing used for finding free spectrum that can then be used in an opportunistic manner is a key task in cognitive radio systems. It enables agile spectrum use and effective management of interference with primary users. Recently, there has been increasing interest on developing low complexity, robust and reliable spectrum sensing methods for detecting the presence of primary users such as cellular subscribers, with whom the cognitive radio secondary users are obligated to avoid interfering. Primary users operate in networks that have radio resources (time and frequency) allocated by regulatory bodies and network access nodes. Often the individual primary user equipments have specifically allocated radio resources for their transmissions and receptions. Cognitive radio networks use spectrum in an opportunistic manner and thus rely on spectrum sensing to find holes in the spectrum for their transmissions which will avoid interfering with the primary users. A cognitive radio may then adapt its parameters such as carrier frequency, power and waveforms dynamically in order to provide the best available connection and to meet the user's needs within the constraints on interference. Regardless of how wide is the band that the spectrum sensing task is to investigate, spectrum sensing must be designed to use low power so as not to deplete by the sensing task the portable power supply of the mobile stations.

Spectrum sensing can be realized for example by using cyclostationary feature detection, by which we mean detecting cyclostationarity properties of the known communication signals. Cyclostationary feature detection is a method for detecting primary users well below the noise level. A signal is cyclostationary when the autocorrelation function of the signal is periodic in time. Communication signals usually have cyclostationary features since, e.g., the coding or modulation introduces periodic statistical properties to them. Noise however, has a time invariant autocorrelation function and thus possesses no cyclostationary features. Hence, cyclostationary feature detection has particularly good performance at low signal-to-noise (SNR) regimes.

Communication signals are typically cyclostationary, and have many periodic statistical properties (such as mean and autocorrelation). Such periodicity may be related to the symbol rate, the coding and modulation schemes as well as the guard periods, for example. Cyclostationarity allows for distinguishing among different transmission types and users if their signals have distinct cyclic frequencies. Thus, primary user detection can for example be based on detecting the cyclostationary features of the primary user signals.

One statistical test for the presence of cyclostationarity is detailed in a paper by A. V. Dandawate & G. B. Giannakis, “STATISTICAL TESTS FOR PRESENCE OF CYCLOSTATIONARITY”, IEEE Transactions on Signal Processing, Vol. 42, No. 9, pp. 2355-2369, 1994. Its performance has been studied in various publications in a theoretical level, but there is no practical implementation available in the literature of which the inventors are aware. For example the method used in the academic studies involves a FFT of a length depending on the number of signal samples which can add up to 10⁵ or more. This of course is not practically realizable in a portable device operating as a cognitive radio. Simply using a fixed length FFT of a reasonable length, the performance of the algorithm is not seen to be sufficient.

The cyclostationary feature detection of the above-referenced Dandawate & Giannakis paper is based on the hypothesis testing problem formulated as:

H₀:∀αÅA and ∀{τₙ}ₙ₌₁^{N}= [symbol] \hat{r}_{xx*}(α)=(α) (1)

H₀: for some α∈A and for some{τₙ}ₙ₌₁^{N} [symbol] \hat{r}_{xx*}(α)=r_{xx*}(α)+ε_{xx*}(α); (2)

where H₀ indicates that no primary user signal is present and H₁ indicates that a primary user signal is present, ε_{xx*}(α) is the estimation error for candidate cyclic frequency a and τₙ is a time delay.

First one estimates the cyclic covariances \hat{r}_{xx*}(α) at the cyclic frequencies of interest αÅA. Under H₀ the estimated cyclic covariances consist of only estimation error ε_{xx*}(α) and under H₁ the estimated cyclic covariances consist of the cyclic covariances r_{xx*}(α) and the estimation error ε_{xx*}(α) for some α∈A.

The cyclic covariances are estimated at the candidate cyclic frequency α at different lags τₙ (N lags in total) and are stacked at the vector:

\hat{r}_{xx*}(α)=└Re{\hat{R}_{xx*}(α,τ₁)}, . . . ,Re{\hat{R}_{xx*}(α,τ_{N})},Im{\hat{R}_{xx*}(α,τ₁)}, . . . ,Im{\hat{R}_{xx*}(τ,τ_{N})}┘. (3)

Here the estimate of the cyclic autocorrelation is

$${\hat{R}}_{{xx}^{*}} ( α , τ ) = \frac{1}{M} {\sum }_{t = 1}^{M} x ( t ) {x}^{*} ( t + τ ) {e}^{- j 2 π α t} , \qquad ( 4 )$$

where x(t) denotes the sampled data. The estimation error ε_{xx*}(α) is asymptotically normally distributed as M goes to infinity.

The test statistic for the hypothesis test is defined as

$${T}_{{xx}^{*}} ( α ) = M {\hat{r}}_{{xx}^{*}} {Σ}_{{xx}^{*}}^{- 1} {\hat{r}}_{{xx}^{*}}^{T} , \qquad ( 5 )$$

where the asymptotic covariance matrix is

$${Σ}_{{xx}^{*}} ( α ) = [ \begin{matrix}Re \{ \frac{Q + {Q}^{*}}{2} \} & Im \{ \frac{Q - {Q}^{*}}{2} \} \\ Im \{ \frac{Q + {Q}^{*}}{2} \} & Re \{ \frac{{Q}^{*} - Q}{2} \}\end{matrix} ] . \qquad ( 6 )$$

The entries to the covariance matrix are calculated as

Q(m,n)=S_{f}_{_{τm}}_{f}_{_{τm}}(2α,α)

Q*(m,n)=S*_{f}_{_{τm}}_{f}_{_{τm}}(0,−α)′ (7)

where the unconjugated and conjugated cyclic spectra of f(t,τ)=x(t)x*(t+τ) are estimated using

$$\begin{matrix}{S}_{{f}_{τ m} {f}_{τ n}} ( 2 α , α ) = \frac{1}{MT} {\sum }_{s = - ( T - 1 ) / 2}^{( T - 1 ) / 2} W ( s ) {F}_{τ n} ( α - \frac{2 π s}{M} ) {F}_{τ m} ( α + \frac{2 π s}{M} ) \\ {S}_{{f}_{τ m} {f}_{τ n}}^{*} ( 0 , - α ) = \frac{1}{MT} {\sum }_{s = - ( T - 1 ) / 2}^{( T - 1 ) / 2} W ( s ) {F}_{τ n}^{*} ( α + \frac{2 π s}{M} ) {F}_{τ m} ( α + \frac{2 π s}{M} ) \\ and & ( 8 ) \\ {F}_{τ} ( ω ) = \sum x ( t ) {x}^{*} ( t + τ ) {e}^{- j α x} . & ( 9 )\end{matrix}$$

W(s) is a normalized spectral window of length T. Under H₀ the test statistic T_{xx*}(α) is asymptotically χ_{2N}² distributed. Here, the FFT length is defined by the number of samples of the signal as one can see from equations (4) and (9).

Other references detailing cyclostationarity based detectors include:
J. Lunden, V. Koivunen, A. Huttunen, H. V. Poor, entitled “SPECTRUM SENSING IN COGNITIVE RADIOS BASED ON MULTIPLE CYCLIC FREQUENCIES”, PROCEEDINGS OF 2^{ND} INTERNATIONAL CONFERENCE ON COGNITIVE RADIO ORIENTED WIRELESS NETWORKS AND COMMUNICATIONS, Orlando, Fla., Jul. 31-Aug. 3, 2007;

What is needed in the art is a way to adapt a statistical test for the presence of cyclostationarity, such as the test presented in the above-referenced Dandawate & Giannakis paper, for use in a portable device that would be operating as a cognitive radio. Such adaptation would account for the limited processing capacity and power supply of such a portable device while still achieving adequate performance so as to effectively manage any interference with the primary users due to the cognitive spectrum usage.

### SUMMARY

In accordance with an exemplary embodiment of the invention is a method that includes extracting samples from a received signal. Further in the method, for each of a plurality of candidate cyclic frequencies, covariance of the received signal is determined using a Fourier transform having a length that is less than the number of extracted samples. The method continues with either or both of opportunistically transmitting on a radio frequency channel within which the signal was received for the case where none of the plurality of candidate cyclic frequencies exhibits a peak that exceeds a threshold, or transmitting a result from the determined cyclic covariance to other users or a central node.

In accordance with an exemplary embodiment of the invention is an apparatus that includes a receiver and a processor and a transmitter. The receiver is configured to receive a signal. The processor is configured to extract samples from a received signal, and to determine, for each of a plurality of candidate cyclic frequencies, cyclic covariance of the received signal using a Fourier transform having a length that is less than the number of extracted samples. The transmitter is configured to opportunistically transmit on a radio frequency channel within which the signal was received for the case where none of the plurality of candidate cyclic frequencies exhibits a peak that exceeds a threshold, and/or to transmit a result from the determined cyclic covariance.

In accordance with an exemplary embodiment of the invention is a memory embodying a program of computer readable instructions, executable by a processor to perform actions directed to finding an opportunistic frequency channel. In this embodiment the actions include extracting samples from a received signal; and for each of a plurality of candidate cyclic frequencies, determining cyclic covariance of the received signal using a Fourier transform having a length that is less than the number of extracted samples. The actions further include opportunistically transmitting on a radio frequency channel within which the signal was received for the case where none of the plurality of candidate cyclic frequencies exhibits a peak that exceeds a threshold, and/or transmitting a result from the determined cyclic covariance.

In accordance with an exemplary embodiment of the invention is an apparatus that includes sampling means (e.g., a digital sampler, or more generally a processor) and processing means (e.g., a digital data processor) and sending means (e.g., a wireless transmitter). The sampling means is for extracting samples from a received signal. The processing means is for determining, for each of a plurality of candidate cyclic frequencies, cyclic covariance of the received signal using a Fourier transform having a length that is less than the number of extracted samples. And the sending means is for opportunistically transmitting on a radio frequency channel within which the signal was received for the case where none of the plurality of candidate cyclic frequencies exhibits a peak that exceeds a threshold, and/or for transmitting a result from the determined cyclic covariance.

### BRIEF DESCRIPTION OF THE DRAWINGS

FIG. 1 is a plot showing cyclic spectrum peaks for a WLAN signal.

FIG. 2 is a plot showing detection probability for a WLAN signal as a function of signal-to-noise ratio (AWGN) for various signal sample sizes.

FIG. 3 is a plot showing probability of detection for a WLAN signal with decimation factors M=4 and M=2 and FFT lengths 4096 and 2048, respectively.

FIG. 4 is a plot showing probability of detection for a WLAN signal with FFT length 4096 and with decimation factors M=4 and M=8.

FIG. 5A is a simplified block diagram of various electronic devices that are suitable for use in practicing the exemplary embodiments of this invention.

FIG. 5B is a block diagram showing further detail over FIG. 5A for a particular embodiment of the invention.

FIG. 6 is a block diagram illustrating a radio environment in which a cognitive radio of FIG. 5A operates, including primary users whose signals are not to be interfered.

FIG. 7 is process flow diagram according to an exemplary embodiment of the invention.

### DETAILED DESCRIPTION

In order to provide a statistical test for cyclostationary feature detection that may be reasonably implemented in a portable device, there is provided in accordance with one embodiment of the invention a cyclostationary feature detection algorithm for detecting primary signals that is modified from the algorithm introduced in the Dandawate & Giannakis paper. Such implementation is not seen to be a straightforward realization of the Dandawate & Giannakis approach, but the modifications presented herein are specifically tailored toward making such a statistical feature detection test viable in practice for a cognitive radio. Specifically, in an embodiment the FFT length that the Dandawate & Giannakis paper details is modified so as to be less than the length of the signal. This necessarily means that in different instances of searching for available spectrum, the FFT length differs. Thus the FFT length can take on varying values.

The inventors have evaluated FFT length for various systems, and have found that at least 16384, 65536, and 131072 are feasible lengths of the FFT for WLAN, LTE, and DVB-T, respectively, in order to achieve a moderate level of performance. This is not a limit to which communication systems for primary users may be evaluated, but exemplary of three common ones. As will be seen below, these FFT lengths can be further reduced a length that is a power of 2 that is even more simple to implement with little reduction in performance as compared to the longer FFT lengths. Embodiments of the invention employ extra signal processing steps of filtering and decimation so that a FFT of a reasonable length can be used.

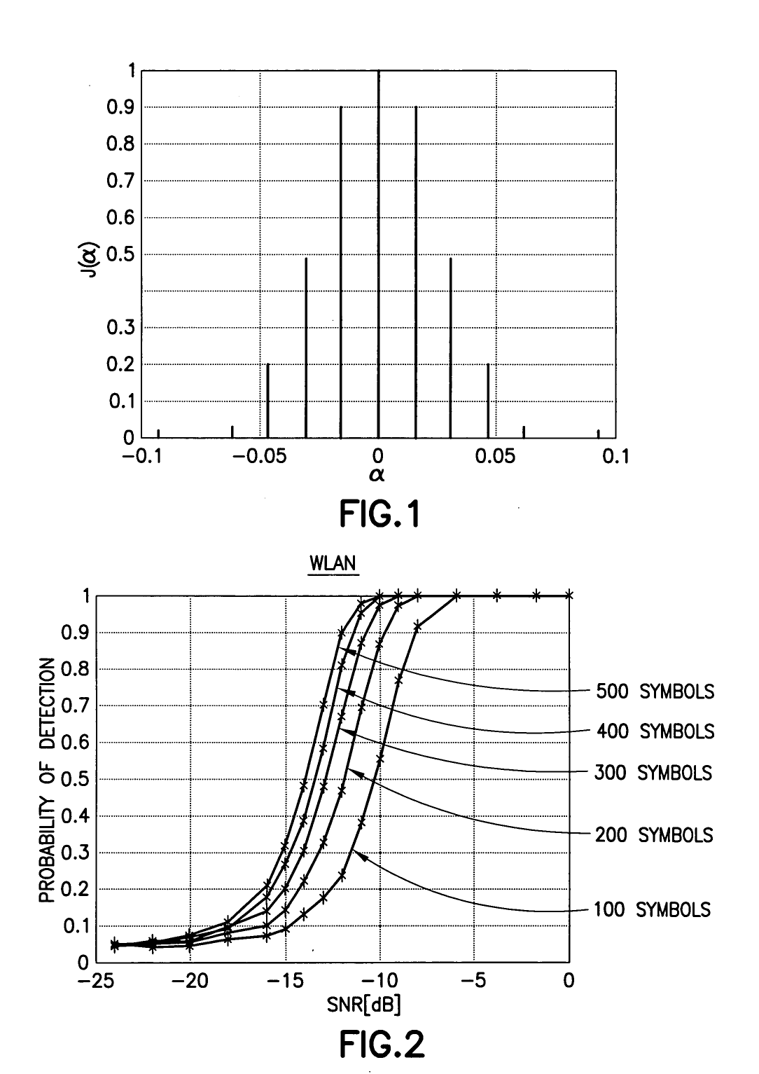

In cyclostationary feature detection the cyclic spectrum of the signal is investigated, such as by finding autocorrelation peaks as shown at FIG. 1. The cognitive radio passively receives signals that are in the air interface, which at this juncture the cognitive radio does not know whether they are noise or primary user signals with which it is to avoid interference. As is known in the art, these received analog signals are digitally sampled. From knowledge of other wireless communication systems, there is a set of cyclic frequencies of interest that the cognitive radio explores. If there is cyclic covariance of the digital samples at one of these known and predetermined cyclic frequencies of interest, then the cognitive radio can reasonably conclude that the signal from which the digital samples are taken is a primary user signal, and should avoid transmitting in the radio frequency range in which that signal was received. Note the cyclic frequency is not the same as a radio frequency. An example of a cyclic frequency is an ODFM symbol rate as may be published in a wireless protocol for OFDM communications, whereas a radio frequency is given by an oscillator frequency. Cyclostationary feature detection is used to find the cyclic frequencies. The extent of the cyclic covariance is represented as a peak as seen at FIG. 1. Cyclostationary feature detection is a statistical evaluation, and so if the peak exceeds some predetermined threshold the cognitive radio concludes that it is a peak, and if it does not then the cognitive radio concludes there is no peak and thus no cyclostationary feature at the candidate cyclic frequency. The threshold is set to guarantee some desired statistical confidence level and its exact setting is not further detailed. If the cyclic spectrum concludes a peak at the cyclic frequency of interest, it can be deduced that the cyclostationary feature is present. At FIG. 1, the horizontal axis is the cyclic frequency alpha. The peaks at integer multiples of the symbol rate 1/(52+13) indicate that the signal exhibits cyclostationarity.

There can be a plurality of cyclic frequencies that the cognitive radio investigates per signal. The number depends on several factors, particularly how many primary systems against which the received signal will be tested. For the case where the cognitive radio analyzes the signal only with respect to an OFDM based communication system such as a WLAN system, the detection can be made based on one or two features. An OFDM signal with a cyclic prefix exhibits cyclostationarity at integer multiples of the ODFM symbol rate or carrier frequency, for example. For the case where the cognitive radio evaluates for whether the signal is within any of several primary communication systems, the number of features tested will rise accordingly, and if the signal is primary in any of them the cognitive radio is to avoid interference with that signal. If in fact a peak is found at a cyclic frequency known to be due to a primary user, then the cognitive radio discounts for the time being the frequency channel in which that signal was received and seeks another signal in a different frequency channel to analyze.

It is noted that FIG. 1 is plotted from an analyzed OFDM modulated WLAN signal. The sum with respect to frequency has been plotted for each cyclic frequency α. The cyclic spectrum of the WLAN signal exhibits the peaks corresponding to the OFDM symbol length T_{sampling}/T_{symbol}=1/(52+13)=0.0154 and its integer multiples. Here the FFT length of the OFDM modulated WLAN signal is T_{FFT}=52 and the cyclic prefix length is T_{CP}=13. The time delays τₙ used in the calculation are equal to ±T_{FFT}.

The performance of the algorithm of Dandawate & Giannakis is shown at FIG. 2, which illustrates the detection probability of a WLAN signal as a function of signal-to-noise ratio (additive white Gaussian noise AWGN) for various signal sample sizes. The detection probability of the WLAN signal is based on detecting the cyclic frequency α=0.0154. In the curves representing the performance for varying numbers of signal samples, the FFT length is always larger than or equal to the number of signal samples. Thus, when 100 OFDM symbols are considered (equal to 100*64 signal samples), the FFT length is 8192 (one half the size 16384 presented above as a feasible FFT length). When 200 symbols are considered (equal to 200*64 signal samples), the FFT length is 16384, and so on depending on the number of signal samples. While these FFT lengths do vary with the number of samples taken from the signal as broadly noted above for how these teachings modify the prior art cyclostationary feature detection, below are noted how the number of samples considered for such feature detection may be truncated even further without substantial decrease in performance.

Further to the above, filtering and decimation may be conducted prior to the FFT calculation in order to be able to use a FFT of length on the order of 2048 or 4096 for example. More generally, in an embodiment there are a number of FFT lengths that are predetermined, each being equal to a power of two which is convenient for digitized samples. The selected FFT length is the shortest of those predetermined FFT lengths that at least equals the number of samples after filtering and decimating. The cyclic frequency that indicates the cyclostationary feature is different for each primary user and depends on the signal parameters (as noted above, for an OFDM-modulated signal a good cyclostationary feature appears at the cyclic frequency that is equal to OFDM symbol rate). The cyclic frequencies of interest are predefined for each primary system, since the primary users must know them in advance in order to access the system to begin with. Thus, the cognitive radio can also know these same cyclostationary features in advance and filter the autocorrelation function of the received signal, prior to the FFT processing, with such a filter. As will be seen, such filtering does not adversely impact the performance of the cyclostationary feature detection.

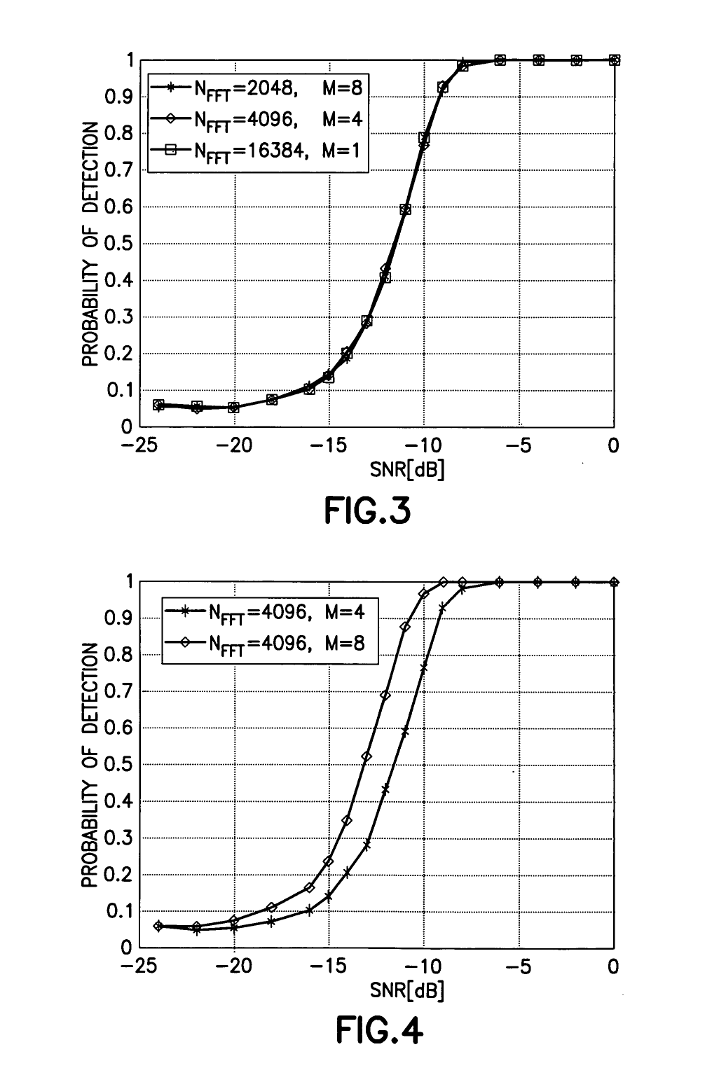

After filtering, the signal can be decimated at a rate which depends on the filter bandwidth. After decimation, a shorter FFT can be used while not affecting the performance of the original algorithm. The proof of this is shown at FIG. 3, which plots the probability of detection of the WLAN signal with decimation factors M=4 and M=8 and FFT lengths 4096 and 2048, respectively. For comparison, the probability of detection without decimation and with FFT of length 16384 is also shown at FIG. 3. There is scant difference in performance when using the shorter 4096/2048 length FFTs. One can therefore see that the FFT size can be reduced from 16384 to 4096 or 2048 without appreciable performance degradation according to these filtering and decimation teachings.

Unlike the Dandawate and Giannakis reference and normal filtering and decimation, these teachings consider the cyclic spectrum, not the signal spectrum. Thus, the filtering and decimation detailed above is done depending on at which cyclic frequencies the signal exhibits cyclostationarity. Since the cyclostationary features of the signals are different, the different primary signals have different cyclic frequencies at which the detection is performed. Thus the FFT length depends on the primary signal which is being detected. Also the decimation factor can be different for different primary signals. The decimation will be done using the highest decimation factor possible which does not filter out the lowest cyclic frequency where the peak is located for the primary signal in question. Then the FFT length that is needed is minimized. Note that the decimation factor here does not depend on signal bandwidth at all.

FIG. 4 is a plot showing performance for different decimation factors, and where other parameters are held constant. Specifically, for a fixed FFT length of 4096 and with decimation factors M=4 and M=8, one can see from FIG. 4 that as the decimation factor is increased, the performance is improved in the same manner as when the number of signal samples is increased as seen at FIG. 2. The proper decimation factor and FFT length is chosen depending on the signal which is detected and the primary user systems against which it is evaluated.

To facilitate implementation in a portable cognitive radio apparatus even more readily, according to another aspect of these teachings a window function is employed that is centered on zero cyclic frequency. The Dandawate & Giannakis paper uses a window that is centered on the cyclic frequency of interest. For implementation this requires an ordering memory type of element. This aspect of these teachings avoids such an ordering memory element in that, since the cyclic frequencies of interest are located close to zero frequency (e.g., OFDM symbol rate=0.0154 as above), a window function that is centered on zero may be used, without affecting the performance of the detection algorithm. The window function spans the candidate cyclic frequencies, but since they are located near zero frequency anyway the window function can be centered on zero cyclic frequency. The results presented in FIG. 4 were calculated using a window centered on zero cyclic frequency.

Now are described exemplary apparatus in which various aspects of the invention might be embodied, and a cognitive radio environment in which they operate and sense spectrum according to these teachings.

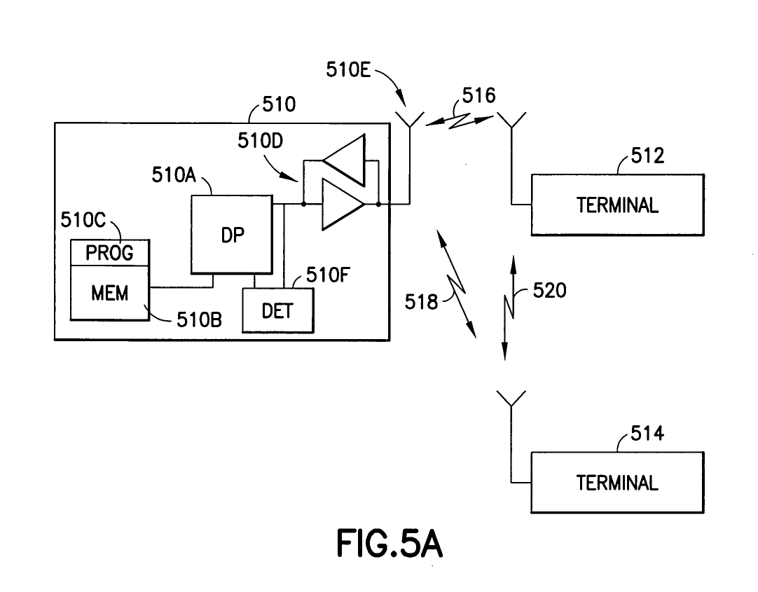

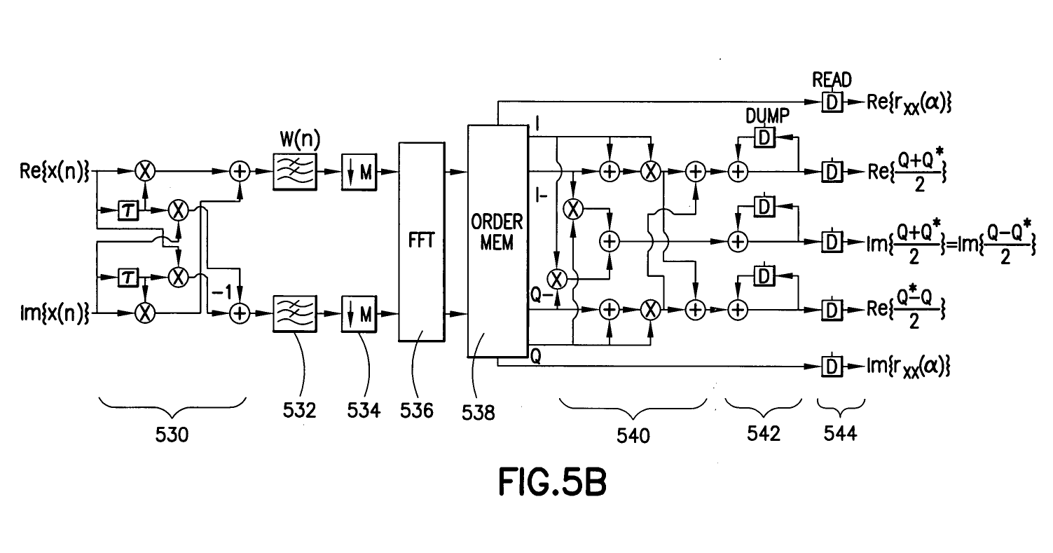

FIG. 5A illustrates simplified block diagrams of various electronic devices that are suitable for use in practicing the exemplary embodiments of this invention. FIG. 5A shows a high level block diagram of three cognitive radio terminals 510, 512, 514. These cognitive radio terminals 510, 512, 514, operate on an opportunistic basis in spectrum channels that are found underutilized by a spectrum sensing functionality. The first cognitive radio terminal 510 includes a data processor (DP) 510A, a memory (MEM) 510B that stores a program (PROG) 510C, and a suitable radio frequency (RF) transceiver 510D coupled to one or more antennas 510E (one shown) for bidirectional wireless communications over one or more wireless links 516, 518 with the other cognitive users 512, 514. A separate detector 510F is shown at the first terminal 510, which in various implementations may be embodied as hardware within the receiver portion of the transceiver 510D, as an application specific integrated circuit ASIC (which may be within the transceiver 510D such as a RF front end chip or separate as illustrated), or within the main DP 510A itself. Also shown in FIG. 5A is a link 520 between those other two cognitive radio terminals 512, 514. It is understood that the other terminals 510, 512 also have similar hardware as is shown for the first terminal 510, and they may or may not find their spectrum holes using detectors for cyclostationary signals according to these teachings. The terminals 510, 512, and 514 can also perform collaborative spectrum sensing by measuring the same spectrum channels, analyzing the measured data and sharing the analyzed results. In one such implementation, one device does not detect all the spectrum channels, but multiple devices each sense different spectrum channels and report their findings to all devices in the network or to an access node that operates as a centralized information node to inform the cognitive radios of which channels are free for cognitive radio communications.

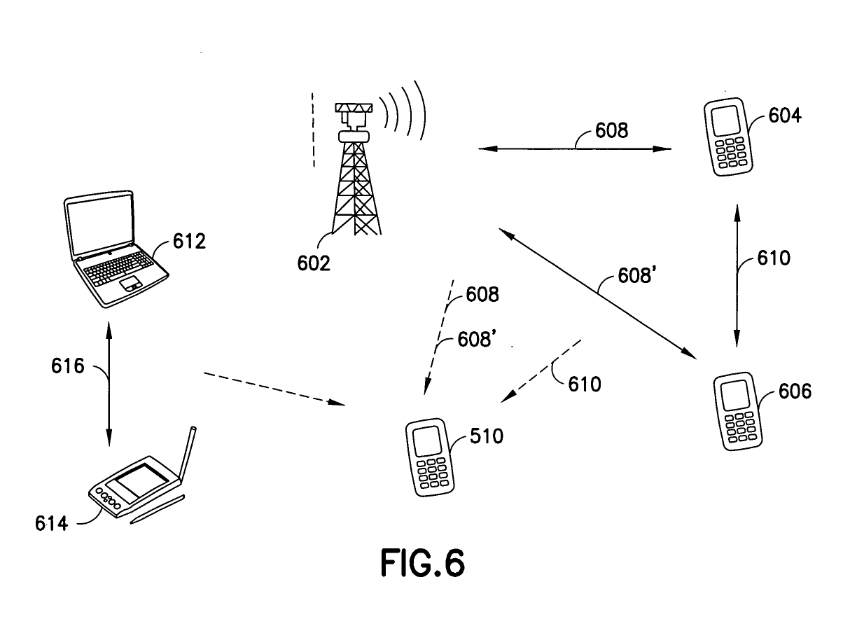

Generally, the spectrum sensing functions detailed herein are executed within the DP 510A or ASIC detector 510F using the transceiver 510D and antenna 510E of the UE 510. Once spectrum is sensed and a ‘hole’ is found, the UE 510 may communicate with the other cognitive radios 512, 514 as may be allowed in the cognitive radio system. The detection techniques detailed herein are for the cognitive radio 510 to sense signals of the primary users, which in FIG. 6 are from devices 612 and 614 operating in a WLAN system and devices 602, 604 and 606 operating in a traditional cellular system. If the cognitive user determines that there is cyclostationarity present at the appropriate cyclic frequencies in the signal that it analyzes, then the cognitive terminal concludes that the signal is from a primary user. The cyclostationarity properties of primary user signal are typically known in advance, as the signaling protocol of WLAN and cellular etc. are pre-published and need not be blind detected. Alternatively such properties may be reliably estimated from a sample signal. In this manner the cognitive users 510, 512, 514 can know those portions of the spectrum that the primary users are currently occupying, and according to these teachings tail or the time and frequencies of their own opportunistic communications with other cognitive users to avoid interfering with those primary users. In addition to the cyclostationarity based detection, the cognitive users can use other methods such as RSSI (received signal strength indication) measurements to detect for example other secondary user systems. There can be a different set of rules for the cognitive use of such a frequency channel where another secondary system has been detected than for a channel where a primary user has been detected. These rules are based on the cognitive radio etiquette.

Cognitive communications are opportunistic in that there might be no access node or hierarchical entity that grants to the cognitive user an authorization to use a particular portion of the radio spectrum, and no formal contention period defined by such a hierarchical entity in which users are constrained to compete for resources that the entity allocates for such contentions.

The terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements can be physical, logical, or a combination thereof. As employed herein two elements may be considered to be “connected” or “coupled” together by the use of one or more wires, cables and printed electrical connections, as well as by the use of electromagnetic energy, such as electromagnetic energy having wavelengths in the radio frequency region, the microwave region and the optical (both visible and invisible) region, as non-limiting examples.

At least one of the PROGs 510C is assumed to include program instructions that, when executed by the associated DP, enable the electronic device to operate in accordance with the exemplary embodiments of this invention, as detailed above. Inherent in the DP 510A is a clock (oscillator) to enable synchronism among the various apparatus for transmissions and receptions within the appropriate time intervals and slots required.

The PROG 510C may be embodied in software, firmware and/or hardware, as is appropriate. In general, the exemplary embodiments of this invention may be implemented by computer software stored in the MEM 510B and executable by the DP 510A of the cognitive radio terminal/user equipment 510, or by hardware, or by a combination of software and/or firmware and hardware in any or all of the devices shown.

In general, the various embodiments of the cognitive radio terminal/UE 510 can include, but are not limited to, mobile terminals/stations, cellular telephones, personal digital assistants (PDAs) having wireless communication capabilities, portable computers (e.g., laptops) having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions and sensor networks.

The MEM 510B may be of any type suitable to the local technical environment and may be implemented using any suitable data storage technology, such as semiconductor-based memory devices, magnetic memory devices and systems, optical memory devices and systems, fixed memory and removable memory. The DP 510A/ASIC 510F may be of any type suitable to the local technical environment, and may include one or more of general purpose computers, special purpose computers, microprocessors, digital signal processors (DSPs) and processors based on a multi-core processor architecture, as non-limiting examples.

FIG. 5B is a particular embodiment of the detector 510F of the cognitive radio 510 of FIG. 5A. Both real and imaginary components of the digital samples taken from the received signal are input on the separate lines of FIG. 5B. These are fed to a complex multiplier 530 which computes the product of the input signal and its delayed (τ) and conjugated (−1) version. When the cyclostationary feature detection as implemented specifically uses the algorithm of the Dandawate & Giannakis paper (but with the variable length FFT), this product is required to compute equation (9) above.

This product is then fed to a low-pass filter 532 denoted by W(n). The frequency domain amplitude response of the filter 532 W(n) at FIG. 5B is a square-root of the filter W(s) of equation (8). In equation (8), a product of two square-roots W(n) equals the amplitude response of W(s). After filtering, the sampling rate Fₛ can be lowered by the factor M at downsampler/decimator 534, since filtering removes the frequency components above Fₛ/(2M).

After decimation, the discrete Fourier transformation (DFT) is computed according to equation (9) above by a FFT processor unit 536, which as seen at FIG. 5A may be within a main processor 510A, an ASIC 510F, or for fastest response within the RF front end chip denoted in FIG. 5A as the transceiver 510D. The results of the FFT (output of the FFT processing unit 536) are arranged in an ordering memory unit 538 in order to align the frequency indexes of the FFT according to equation (8) before multiplication. The ordering memory unit 538 also produces the cyclic frequency component r_{xx*}(α).

The output of the ordering memory unit 538 is then fed to a complex multiplier 540 and thereafter to an integrate-and-dump type of integrator 542 that performs the multiplication and summation shown at equation (8). This produces the terms of equation (6).

The “read” signal (readout registers 544) is used to read the results to the rightmost side of FIG. 5B to an external microprocessor (e.g., DP 510A) that performs the actual statistical test for H₀. The “dump” signal (from the dump registers D) is for resetting the feedback loop of the integrator 542.

FIG. 6 is a simple schematic illustration of a cognitive radio environment. Assume for example that signals 616 between access point 612 and user 614 are WLAN, and signals 608, 608′ between base station 602 and mobile terminals 604, 606 are cellular (e.g., E-UTRAN, UTRAN, GSM, WCDMA, and the like). Also shown is device to device communications 610 between the two cellular mobile stations 604, 606, but this link 610 operates with radio resources allocated by the base station 602 and for these purposes are thus signals not unlike the regular uplink/downlink signals 608, 608′ between mobile terminal and base station, so they will exhibit the same cyclostationary features as those uplink/downlink signals. These devices 602, 604, 606, 612, 614 are the primary users whose signals 608, 608′, 610, 616 the cognitive radio 510 seeks to avoid interfering by its opportunistic transmissions. All users in FIG. 6 are operating in the same geographic vicinity or user area.

Cognitive radio 510 uses the cyclostationary feature detection teachings detailed herein on the primary user signals 608, 608′, 610, 612 that it passively receives (passive reception shown as dashed lines) and actively analyzes to find opportunistic holes in the spectrum that it can use, as those holes would otherwise be wasted radio resources. These opportunistic ‘holes’ arise and fade as time passes since traffic on the other bands (WLAN, cellular) varies over time, so the cognitive radio 510 must continue to engage in spectrum sensing in order to keep up their communications as secondary users. Not shown at FIG. 6 are the other cognitive radios 512, 514 with which the illustrated radio 510 is communicating, though they are present in the same geographic vicinity and perform their own spectrum sensing and feature detection. The illustrated cognitive radio 510 may communicate with one other radio 512, 514 as in direct device to device voice communications, or with multiple other cognitive radios as in a multi-user gaming application in which data is exchanged between more than two cognitive radio devices simultaneously. In other embodiments the cognitive radio 510 may also or alternatively communicate with an access point of a wireless network, such as the base station 602 of FIG. 6.

As can be seen, the shortened FFT presented herein as compared to the FFT length defined by the Dandawate & Giannakis paper enable cyclostationary feature detection to be implemented in a portable cognitive radio device, which is not seen as practical absent these modifications due to the high power consumption of the long FFT.

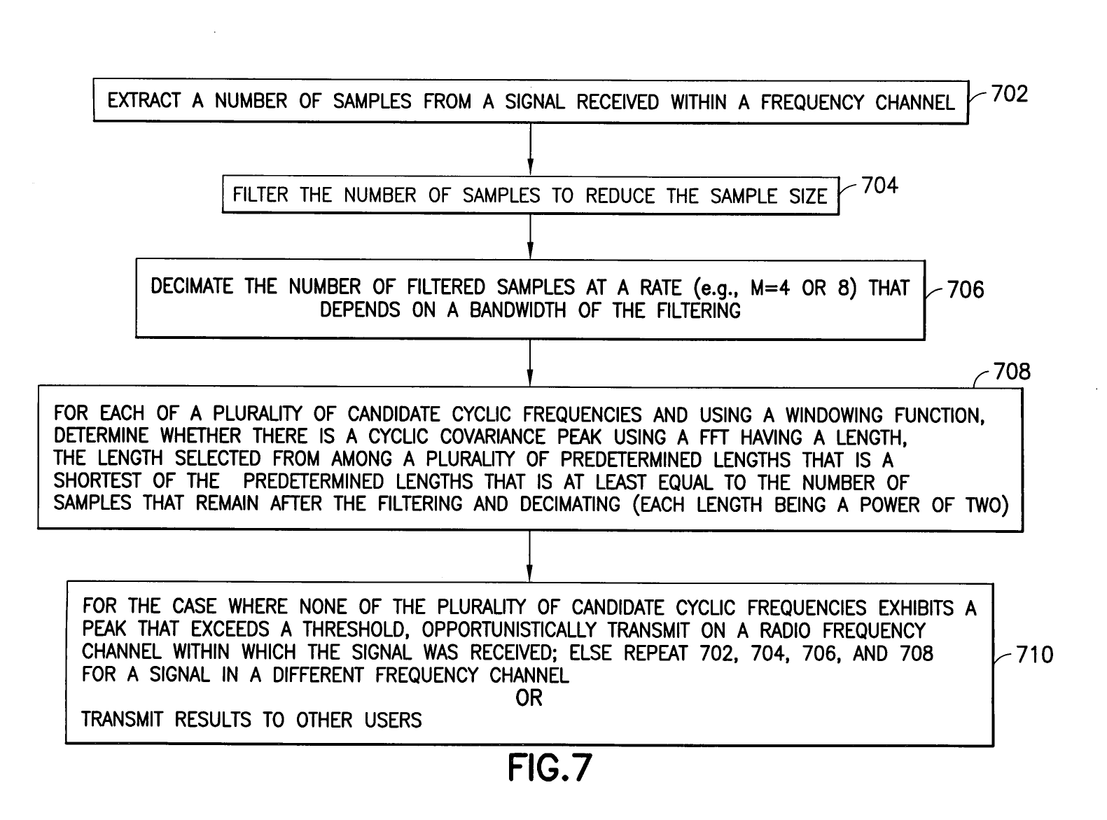

FIG. 7 is a process flow diagram showing exemplary process steps according to an exemplary embodiment of the invention. At block 702, a number of samples are extracted from a received signal. At block 704 the number of samples are filtered, and at block 706 the number of filtered samples are decimated at a rate (e.g., M=4 or 8) that depends on a bandwidth of the filtering. In a particular embodiment, the filtering is at a bandwidth that depends on the cyclic spectrum of the received signal, specifically the lowest cyclic frequency where the signal exhibits cyclostationarity. Of course one may filter at a bandwidth based on two or more cyclic frequencies of the received signal with a bit more increased processing overhead, and those two or more cyclic frequencies may or may not include the lowest cyclic frequency as above (which includes integer multiples of the lowest cyclic frequency). In other embodiments the filtering at this juncture may be eliminated altogether.

At block 708, for each of a plurality of candidate cyclic frequencies, cyclic covariance of the received signal is determined using a Fourier Transform (DFT executed in the FFT processing unit) having a length that is less than the number of extracted samples. Specifically and as detailed above, the length of the Fourier Transform depends on the number of samples that remain after the filtering and decimating, and the length is selected from among a plurality of predetermined lengths such that the selected length is a shortest of all the predetermined lengths that is at least equal to the number of samples that remain after the filtering and decimating. As noted above, it is convenient that each of these predetermined lengths is equal to a power of 2.

Each of the plurality of candidate frequencies are predetermined and defined by at least one wireless system for primary users. For example, one of those candidate cyclic frequencies is equal to a symbol rate for an orthogonal frequency division multiplex system. Block 708 may also employ a window function centered on zero cyclic frequency that spans the plurality of candidate cyclic frequencies.

At block 710, for the case where none of the plurality of candidate cyclic frequencies exhibits a peak that exceeds a threshold, then the cognitive radio opportunistically transmits on a radio frequency channel within which the signal was received. This lack of a peak indicates that the received signal that was analyzed was noise and not a primary user signal. If in fact there is a peak, the received signal is concluded to be a primary user signal and another signal is received in a different frequency channel and the process continues from the start until a signal that is concluded as noise is found. The cognitive radio system might also be performing collaborative spectrum sensing where different devices analyze different spectrum channels and report their results to other devices in the cognitive radio network as shown at the lower portion of block 710. Of course, any cognitive radio can transmit its results to other devices, receive the results of other cognitive radio devices for different portions of the spectrum, and then opportunistically transmit based on the combined analysis of its own results and those it wireless receives from the other cognitive radio devices.

In general, the various embodiments may be implemented in hardware or special purpose circuits, software (computer readable instructions embodied on a computer readable medium), logic or any combination thereof. While various aspects of the invention may be illustrated and described as block diagrams, flow charts, or other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

Embodiments of the inventions may be practiced in various components such as integrated circuit modules. The design of integrated circuits ICs is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

Various modifications and adaptations may become apparent to those skilled in the relevant arts in view of the foregoing description, when read in conjunction with the accompanying drawings. However, any and all modifications of the teachings of this invention will still fall within the scope of the non-limiting embodiments of this invention.

Although described in the context of particular embodiments, it will be apparent to those skilled in the art that a number of modifications and various changes to these teachings may occur. Thus, while the invention has been particularly shown and described with respect to one or more embodiments thereof, it will be understood by those skilled in the art that certain modifications or changes may be made therein without departing from the scope and spirit of the invention as set forth above, or from the scope of the ensuing claims.

We claim:

1. A method comprising:
extracting samples from a received signal;
for each of a plurality of candidate cyclic frequencies, determining cyclic covariance of the received signal using a Fourier transform having a length that is less than the number of extracted samples; and
opportunistically transmitting on a radio frequency channel within which the signal was received for the case where none of the plurality of candidate cyclic frequencies exhibits a peak that exceeds a threshold, or transmitting a result from the determined cyclic covariance.

2. The method of claim 1, wherein the Fourier transform is a discrete Fourier transform executed by a Fast Fourier transform processor unit.

3. The method of claim 1, further comprising filtering and decimating the extracted samples prior to executing the Fourier transform, and wherein the length of the Fourier transform depends on the number of samples that remain after the filtering and decimating.

4. The method of claim 3, wherein the decimating is at a rate that is independent of a bandwidth of the filtering.

5. The method of claim 4, wherein the rate is four or eight.

6. The method of claim 4, wherein the filtering is at a bandwidth that depends on a lowest cyclic frequency at which the received signal exhibits cyclostationarity.

7. The method of claim 3, wherein the length is selected from among a plurality of predetermined lengths such that the selected length is a shortest of the plurality of predetermined lengths that is at least equal to the number of samples that remain after the filtering and decimating.

8. The method of claim 7, wherein the plurality of the predetermined lengths include 2048 and 4096.

9. The method of claim 1, wherein each of the plurality of candidate frequencies are predetermined and defined by at least one wireless system for primary users.

10. The method of claim 9, wherein at least one of the plurality of candidate cyclic frequencies is equal to a symbol rate for an orthogonal frequency division multiplex system.

11. The method of claim 1, wherein each of the plurality of candidate cyclic frequencies are near zero and wherein determining cyclic covariance of the received signal for each of the plurality of candidate cyclic frequencies comprises employing a windowing function centered on zero cyclic frequency that spans the plurality of candidate cyclic frequencies.

12. A memory embodying a program of computer readable instructions, executable by a processor to perform actions directed to finding an opportunistic frequency channel, the actions comprising:
extracting samples from a received signal;
for each of a plurality of candidate cyclic frequencies, determining cyclic covariance of the received signal using a Fourier transform having a length that is less than the number of extracted samples; and
opportunistically transmitting on a radio frequency channel within which the signal was received for the case where none of the plurality of candidate cyclic frequencies exhibits a peak that exceeds a threshold, or transmitting a result from the determined cyclic covariance.

13. The memory of claim 12, the actions further comprising filtering and decimating the extracted samples prior to executing the Fourier transform, and wherein the length of the Fourier transform depends on the number of samples that remain after the filtering and decimating.

14. The memory of claim 13, wherein the decimating is at a rate that is independent of a bandwidth of the filtering and the filtering is at a bandwidth that depends on a lowest cyclic frequency at which the received signal exhibits cyclostationarity

15. The memory of claim 13, wherein the length is selected from among a plurality of predetermined lengths such that the selected length is a shortest of the plurality of predetermined lengths that is at least equal to the number of samples that remain after the filtering and decimating.

16. The memory of claim 12, wherein each of the plurality of candidate cyclic frequencies are near zero and wherein determining cyclic covariance of the received signal for each of the plurality of candidate cyclic frequencies comprises employing a windowing function centered on zero cyclic frequency that spans the plurality of candidate cyclic frequencies.

17. An apparatus comprising:
a receiver configured to receive a signal;
a processor configured to extract samples from a received signal;
the processor further configured to determine, for each of a plurality of candidate cyclic frequencies, cyclic covariance of the received signal using a Fouriertransform having a length that is less than the number of extracted samples; and
a transmitter configured to opportunistically transmit on a radio frequency channel within which the signal was received for the case where none of the plurality of candidate cyclic frequencies exhibits a peak that exceeds a threshold, or configured to transmit a result from the determined cyclic covariance.

18. The apparatus of claim 17, wherein the apparatus further comprises a filter and the processor with the filter are configured to filter and decimate the extracted samples prior to the processor executing the Fourier transform, and wherein the length of the Fourier transform depends on the number of samples that remain after the filtering and decimating.

19. The apparatus of claim 18, wherein the processor is configured to decimate at a rate that is independent of a bandwidth of the filter.

20. The apparatus of claim 19, wherein the rate is four or eight.

21. The apparatus of claim 19, wherein the processor and filter are configured to filter the extracted samples at a bandwidth that depends on a lowest cyclic frequency at which the received signal exhibits cyclostationarity.

22. The apparatus of claim 18, wherein the processor is configured to select the length from among a plurality of predetermined lengths such that the selected length is a shortest of the plurality of predetermined lengths that is at least equal to the number of samples that remain after the filtering and decimating.

23. The apparatus of claim 22, wherein the plurality of the predetermined lengths include 2048 and 4096.

24. The apparatus of claim 17, further comprising a memory storing each of the plurality of candidate frequencies, wherein each of the stored plurality of candidate frequencies are predetermined and defined by at least one wireless system for primary users.

25. The apparatus of claim 24, wherein at least one of the plurality of candidate cyclic frequencies is equal to a symbol rate for an orthogonal frequency division multiplex system.

26. The apparatus of claim 17, wherein each of the plurality of candidate cyclic frequencies are near zero and wherein the processor is configured to determine cyclic covariance of the received signal for each of the plurality of candidate cyclic frequencies by employing a windowing function centered on zero cyclic frequency that spans the plurality of candidate cyclic frequencies.

27. An apparatus comprising:
sampling means for extracting samples from a received signal;
processing means for determining, for each of a plurality of candidate cyclic frequencies, cyclic covariance of the received signal using a Fourier transform having a length that is less than the number of extracted samples; and
sending means for either opportunistically transmitting on a radio frequency channel within which the signal was received when none of the plurality of candidate cyclic frequencies exhibits a peak that exceeds a threshold, or for transmitting a result from the determined cyclic covariance.
